(19) United States
(12) Patent Application Publication
(10) Pub. No.: US 2011/0244761 A1
(43) Pub. Date: Oct. 6, 2011

(54) Method of making conductive Group lll Nitride single crystal substrate

(75) Inventor: Takehiro YOSHIDA, Tsuchiura (JP)

(73) Assignee: Hitachi Cable, Ltd., Tokyo (JP)

(21) Appl. No.: 12/805,557

(22) Filed: Aug. 5, 2010

(30) Foreign Application Priority Data
Apr. 1, 2010 (JP) 2010-084816

(51) Int. Cl. B24B 7/22; H01L 21/322

(52) U.S. Cl. 451/41; 117/2

(57) ABSTRACT

A method of making a conductive group III nitride single crystal substrate includes feeding to a seed crystal a group III raw material gas, a group V raw material gas, and a doping raw material gas diluted with N₂ or Ar to have a predetermined concentration, growing a group III nitride single crystal on the seed crystal at a growth rate of greater than 450 μm/hour and not greater than 2 mm/hour, and doping the group III nitride single crystal with an impurity contained in the doping raw material gas. The doping raw material gas is diluted to be inhibited from reacting with the group V raw material gas so as to allow the group III nitride single crystal to have a specific resistance of not less than 1×10⁻³ Ωcm and not more than 1×10⁻² Ωcm.

The present application is based on Japanese patent application No. 2010-084816 filed on Apr. 1, 2010, the entire contents of which are incorporated herein by reference.

### BACKGROUND OF THE INVENTION

1. Field of the Invention

This invention relates to a method of making a conductive group III nitride single crystal substrate.

2. Description of the Related Art

En recent years, most of GaN single crystal substrates have been produced by using halide vapor phase epitaxy (HVPE). The known method to produce a conductive GaN single crystal substrate by the HVPE is to feed as a doping gas SiHₓCl₄₋ₓ (x=1 to 3), or an O₂, H₂O, H₂S, SiCl₄, GeCl₄, Se₂Cl₂, Te₂Cl₂ or the like, to dope the GaN single crystal grown on a surface of a hetero-substrate (Al₂O₃, SiC or the like) (see below listed JP-A-2000-91234, Journal of Crystal Growth 311 (2009) 3011, Kenji Fujito, Shuichi Kubo, Hirobumi Nagaoka, Tae Mochizuki, Hideo Namita, and Satoru Nagao, and JP-A-2006-193348).

Also, the prior known method to produce a GaN single crystal substrate is to form, over a surface of a hetero-substrate (Al₂O₃, GaAs or the like), various structures to protect the hetero-substrate itself, reduce defects in the GaN single crystal, or to lift the GaN single crystal off the hetero-substrate (see below listed JP-B-3985839).

Further, the known prior method to produce a GaN single crystal substrate is to use a GaN single crystal substrate as a seed crystal, to grow a GaN single crystal over this seed crystal, to form an ingot, and slice the resulting ingot to produce a plurality of GaN single crystal substrates (see below listed JP-A-2006-273716 and JP-A-2003-17420).

Related arts (patent literatures) to the invention are JP-A-2000-91234, JP-A-2006-193348, JP-B-3985839, JP-A-2006-273716, and JP-A-2003-17420.

A related art (non-patent literature) to the invention is Journal of Crystal Growth 311 (2009) 3011, Kenji Fujito, Shuichi Kubo, Hirobumi Nagaoka, Tae Mochizuki, Hideo Namita, and Satoru Nagao.

### SUMMARY OF THE INVENTION

However, with respect to JP-A-2000-91234, JP-A-2006-193348 and JP-B-3985839, producing one GaN substrate requires the use of one hetero-substrate, and is therefore costly. Also, with respect to JP-A-2006-273716 and JP-A-2003-17420, the GaN ingot to be sliced by a wafer slicer to produce the GaN single crystal substrates, requires a margin of a few mm to be cut, and in addition, a further few hundred μm of layers damaged by cutting to be ground at one surface of the GaN ingot, and is therefore costly. Further, with respect to Journal of Crystal Growth 311 (2009) 3011, JP-A-2000-91234, and JP-A-2003-17420, the GaN single crystal growth rate is on the order of one hundred μm/hour, and requires a long period of time for crystal growth to produce the GaN single crystal substrate, which is a few hundred μm thick, and which has a margin of a few mm to be cut, and producing the GaN single crystal substrate is therefore costly.

Accordingly, it is an object of the present invention to provide a method of making a conductive group III nitride single crystal substrate, capable of low cost production of a conductive group III nitride single crystal substrate having a desired specific resistance.

(1) According to one embodiment of the invention, a method of making a conductive group III nitride single crystal substrate comprises:

feeding to a seed crystal a group III raw material gas, a group V raw material gas, and a doping raw material gas diluted with N₂ or Ar to have a predetermined concentration;

growing a group III nitride single crystal on the seed crystal at a growth rate of greater than 450 μm/hour and not greater than 2 mm/hour; and

doping the group III nitride single crystal with an impurity contained in the doping raw material gas,

wherein the doping raw material gas is diluted to be inhibited from reacting with the group V raw material gas so as to allow the group III nitride single crystal to have a specific resistance of not less than 1×10⁻³ Ωcm and not more than 1×10⁻² Ωcm.

In the above embodiment (1) of the invention, the following modifications and changes can be made.

(i) The doping raw material gas is fed to the seed crystal at a partial pressure of not less than 0.5×10⁻⁶ atm.

(ii) The doping raw material gas contains SiH₂Cl₂.

(iii) The group III raw material gas is produced by feeding a chloride gas to one group III raw material of In, Al or Ga heated at a temperature of from 500° C. to 900° C.

(iv) The group V raw material gas comprises NH₃.

(v) The seed crystal comprises one of crystals of Al₂O₃, GaAs, Si, GaN and AlN or one of the crystals with a patterned mask formed thereon.

(vi) The group III nitride single crystal comprises AlₓIn_{y}Ga_{1-x-y}N (0≦x≦1, 0≦y≦1, 0≦x+y≦1).

(vii) The method further comprises:

slicing the group III nitride single crystal at any crystalline plane into substrates; and

double side grinding the substrates so that the thickness of the substrates produced by the slicing is not less than 100 μm and not more than 600 μm.

Points of the Invention

According to one embodiment of the invention, a method of making a conductive group III nitride single crystal substrate allows the SiH₂Cl₂ diluted with N₂ or Ar to inhibit the reaction between the SiH₂Cl₂ and NH₃ gas phases, and therefore the group III nitride single crystal to be grown fast and have the desired specific resistance. Also, the method allows the group III nitride single crystal to be grown at a growth rate ranging greater than 450 μm/hour and not greater than 2 mm/hour, and therefore the long sized ingot formed from that group III nitride single crystal having the desired specific resistance to be fabricated for a short period of time, and thus the conductive group III nitride single crystal substrate to be fabricated from that ingot at low cost.

### BRIEF DESCRIPTION OF THE DRAWINGS

The preferred embodiments according to the invention will be explained below referring to the drawings, wherein:

FIG. 1 is a graph showing the relationship of the specific resistance of GaN ingots to the partial pressure of a SiH₂Cl₂ gas fed;

FIG. 2 is a graph showing the relationship between the GaN single crystal growth rate and the specific resistance of the resulting GaN ingots;

FIG. 3 is a schematic diagram showing an HVPE apparatus;

FIG. 4 is a typical diagram showing ingot slicing;

FIG. 5 is a graph showing the relationship of the specific resistance of GaN substrates to the partial pressure of a SiH₂Cl₂ gas fed in Example 1;

FIG. 6 is a graph showing the relationship of the specific resistance of GaN substrates to the partial pressure of a SiH₂Cl₂ gas fed in Example 2;

FIG. 7 is a graph showing the relationship of the specific resistance of GaN substrates to the partial pressure of a SiH₂Cl₂ gas fed in Example 3;

FIG. 8 is a graph showing the relationship of the specific resistance of GaN substrates to the partial pressure of a SiH₂Cl₂ gas fed in Example 4;

FIG. 9 is a schematic diagram showing a sliced GaN substrate in Example 7;

FIG. 10 is a graph showing the relationship of the specific resistance of GaN substrates to the partial pressure of an NH₃ gas fed in Example 8; and

FIG. 11 is a graph showing the relationship of the specific resistance of GaN substrates to the partial pressure of a SiH₂Cl₂ gas fed in Comparative example 2.

### DETAILED DESCRIPTION OF THE PREFERRED EMBODIMENTS

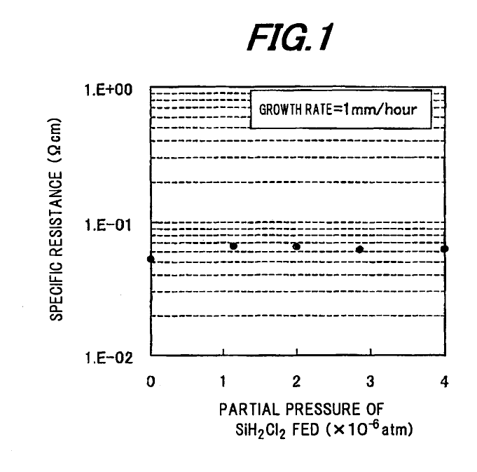

FIG. 1 is a graph showing the relationship of the specific resistance of GaN ingots to the partial pressure of a SiH₂Cl₂ gas fed. In FIG. 1, the growth rate is 1 mm/hour and is constant.

A GaN single crystal ingot is fabricated from a GaN single crystal doped with Si used as an impurity. This Si doped GaN single crystal is grown by the HVPE feeding, to an Al₂O₃ substrate used as a seed crystal, a group III raw material gas, an NH₃ gas used for a group V raw material gas, and a SiH₂Cl₂ gas used for a doping raw material gas. In this case, the growth rate is 1 mm/hour. Also, GaN single crystal ingots are fabricated by varying the partial pressure of the doping raw material gas fed. The specific resistance of each of the resultant ingots is measured. The group III raw material gas comprises GaCl produced by reaction of Ga and a HCl gas fed together with a carrier gas such as H₂ or N₂.

As seen from the measured results shown in FIG. 1, there is substantially no variation in the specific resistance of the resultant ingots, with varying partial pressure of the doping raw material gas fed.

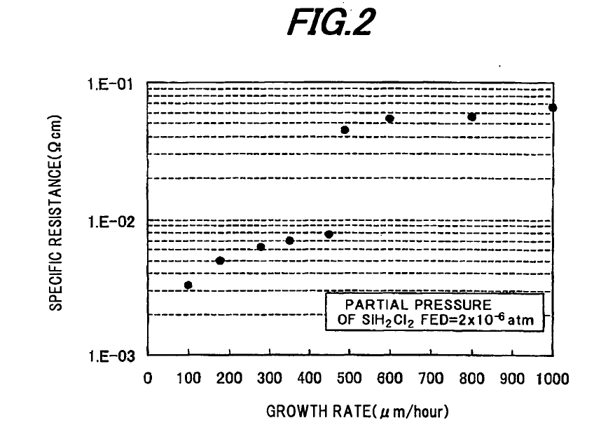

FIG. 2 is a graph showing the relationship between the GaN single crystal growth rate and the specific resistance of the resulting GaN ingots. In FIG. 2, the partial pressure of the SiH₂Cl₂ gas used for the doping raw material gas fed is constant.

With the partial pressure of the SiH₂Cl₂ gas fed being constant, GaN ingots are then fabricated by varying the GaN single crystal growing rate. The partial pressure of the SiH₂Cl₂ gas fed is 2×10⁻⁶ atm.

As seen from the measured results shown in FIG. 2, the specific resistance becomes high sharply when the growth rate exceeds 450 μm/hour.

Next, a comparison is made of high and low specific resistance ingots by secondary ion mass spectrometry (SIMS) testing. From the compared results, it is found that the high specific resistance ingots have a Si concentration, which is lower by a single digit, compared to the low specific resistance ingots.

To reduce the cost for semiconductor device production by slicing the GaN single crystal ingot to produce GaN single crystal substrates, it is essential to grow the GaN single crystal fast. The above-mentioned method allows no sufficient conductivity of the resultant GaN substrates.

Accordingly, the inventors have studied why the specific resistance of the resulting ingots is high (the Si concentration in the ingots is low) at the great growth rates.

From the studied results, it has been found that there is the correlation between the partial pressure of the NH₃ gas fed during ingot growth and the Si concentration in the ingots, i.e., the higher the partial pressure of the NH₃ gas fed during ingot growth, the lower the Si concentration in the resulting ingots.

In other words, since the greater growth rate condition requires the higher partial pressures of both the group III and V raw material gases, the Si concentration in the resulting ingots becomes lower.

The reason for being less doped with Si at the higher partial pressure of the NH₃ gas fed is considered to be because of reaction in vapor phase between SiH₂Cl₂ used for the doping raw material and NH₃ used for the group V raw material before they arrive at the seed crystal.

The inventors have therefore considered that if it is possible to inhibit the vapor phase reaction between SiH₂Cl₂ and NH₃, the Si concentration can be high even in the fast growth condition.

Also, the inventors have considered that the method to inhibit the vapor phase reaction between SiH₂Cl₂ and NH₃ is to use a SiH₂Cl₂ diluting gas, which is relatively small in diffusion coefficient, and inert. The use of the SiH₂Cl₂ diluting gas is considered to allow SiH₂Cl₂ and NH₃ to substantially not mix, and thereby be inhibited from reacting in vapor phase.

Further, the specific resistance (or resistivity) required for the sufficiently conductive GaN substrates is in the range of not less than 1×10⁻³ Ωcm to not more than 1×10⁻² Ωcm, for example. The impurity doping concentration to achieve this range of the specific resistance is in the range of several hundreds to several thousands of ppm. For example, the impurity doping concentration is desirably in the range of about 200 ppm to about 5000 ppm since a doping concentration less than about 200 ppm is insufficient to have the above-required specific resistance and a doping concentration more than about 5000 ppm is too much to suppress the vapor phase reaction between SiH₂Cl₂ and NH₃.

To produce the sufficiently conductive GaN substrates, the SiH₂Cl₂ gas used is therefore diluted to have a specified concentration of several hundreds to several thousands of ppm. For example, the specified concentration is desirably in the range of about 200 ppm to about 5000 ppm. From the point of view of purity, H₂ has previously been used exclusively for the SiH₂Cl₂ diluting gas.

The inventors have thus considered replacing H₂ with N₂ or Ar for the SiH₂Cl₂ diluting gas. Below is described a method of making the conductive group III nitride single crystal substrate. First is described the structure of an HVPE apparatus used in the conductive group III nitride single crystal substrate production.

HVPE Apparatus Structure

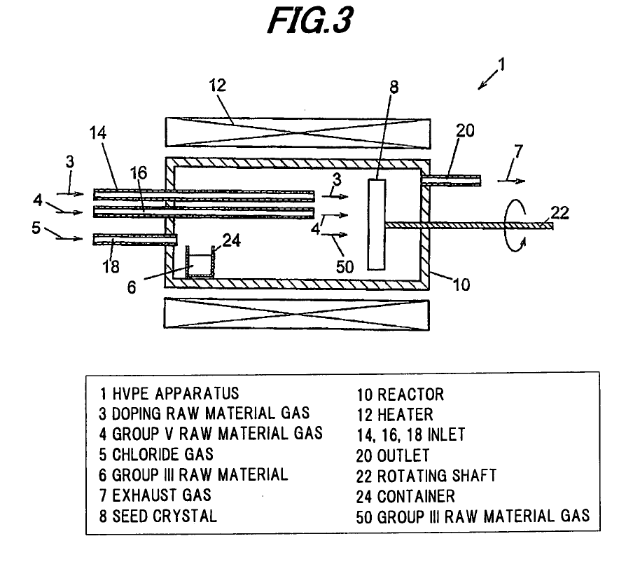

FIG. 3 is a schematic diagram showing an HVPE apparatus. This HVPE apparatus 1 is schematically configured to include a reactor 10, a heater 12, inlets 14, 16, and 18, and an outlet 20.

The reactor 10 is formed of quartz, for example.

The inlet 14 is connected to, for example, the reactor 10, to feed a doping raw material gas 3 into the reactor 10. This doping raw material gas 3 is a N₂ or Ar diluted SiH₂Cl₂ gas, for example. Although the doping raw material gas 3 is produced by SiH₂Cl₂ gas dilution, it is not limited thereto, but may be produced by diluting SiHCl₃, SiH₃Cl, SiCl₄, or a mixture thereof.

The inlet 16 is connected to, for example, the reactor 10, to feed a group V raw material gas 4 into the reactor 10. This group V raw material gas 4 is an NH₃ gas, for example.

The inlet 18 is connected to, for example, the reactor 10, to feed a chloride gas 5 into the reactor 10. This chloride gas 5 is a HCl gas, for example. Also, the chloride gas 5 is fed to a container 24 placed inside the reactor 10. A group III raw material 6 is put in this container 24, and heated by a heater 12. The group III raw material 6 and the chloride gas 5 heated produce a group III raw material gas 50. This group III raw material 6 is In, Al or Ga, for example.

The outlet 20 is connected to, for example, the reactor 10, to vent the gases within the reactor 10 as an exhaust gas 7.

Also, a rotating shaft 22 of the reactor 10 is rotatably connected to the reactor 10, and a seed crystal 8 is fixed to an end of this rotating shaft 22.

This seed crystal 8 is any of Al₂O₃, GaAs, Si, GaN, AlN or these seed crystals with a patterned mask formed thereon, for example.

Conductive Group III Nitride Single Crystal Substrate Production Process

First, the seed crystal 8 is fixed to the rotating shaft 22. With the seed crystal 8 being rotated, the doping raw material gas 3 diluted to have a specified concentration, the group V raw material gas 4, and the group III raw material gas 50 produced from the chloride gas 5 and the group III raw material 6, are fed to the seed crystal 8. The specified concentration is 300 ppm, for example.

The mole ratio of the doping raw material gas 3, the group V raw material gas 4, and the group III raw material gas 50 fed is adjusted to grow a conductive group III nitride single crystal over the surface of the seed crystal 8, to produce an ingot having a desired specific resistance, and a desired composition. The temperature of heating the group III raw material 6 is from 500° C. to 900° C. Also, the temperature of the surface of the seed crystal 8 over which is grown the conductive group III nitride single crystal is adjusted in a range of from 500° C. to 1100° C. according to the crystal grown, for example. The desired specific resistance ranges from not less than 1×10⁻³ Ωcm to not more than 1×10⁻² Ωcm.

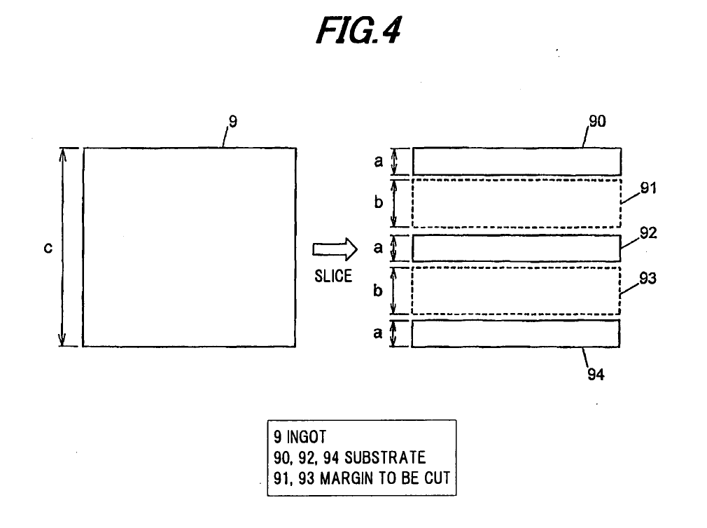

FIG. 4 is a typical diagram showing ingot slicing. Using a wafer slicer, this ingot 9 is sliced into substrates 90, 92, and 94 having a thickness a, as shown in FIG. 4. Assuming that margins 91 and 93 to be cut and lost have a thickness b, the most unwasted thickness c of the ingot 9 to produce a number x of substrates is calculated from Formula 1 below:

c=ax+(x−1)b Formula 1

It is therefore preferred to grow the ingot 9 having the thickness c calculated with Formula 1, taking into consideration the thickness a and the number x of substrates to be cut out from the ingot 9, and the thickness b of the margins to be cut.

Here, assuming that the growth rate of the ingot 9 is r, and that the total time for necessary arrangements to grow the ingot 9 by the HVPE and for increasing temperature and for decreasing temperature is T, the time dₓ for growing one substrate is calculated from Formula 2 below:

dₓ=(c/r+T)/x Formula 2

To reduce cost, the time dₓ for growing one substrate may be shortened. There is a limit for shortening the total time T to ensure improved efficiency. Accordingly, as seen from Formula 2, to make the effect of the total time T small, the thickness c of the ingot 9 may be made great (the ingot 9 may be elongated), and the number x of substrates to be cut out from the ingot 9 may be made great.

It is noted, however, that the time dₓ for growing one substrate cannot be shortened, unless Formula 3 below is held that is derived by substituting Formula 1 in Formula 2 and assuming that the time dₓ for growing one substrate is shorter when the number of substrates to be cut out is x than when it is x−1 (dₓ<dₓ₋₁):

r>b/T Formula 3

Here, the thickness b of the margins to be cut is approximately 1 mm when slicing the ingot 9 using the wafer slicer. Also, the total time T is approximately 2 and half a hour. Thus, by substituting this thickness b of the margins to be cut and this total time T in Formula 3, it is seen that for ingot growth, the growth rate r is required to be greater than 400 μm/hour.

With the growth rate r being greater than 400 μm/hour, the time dₓ for growing one substrate tends to be reduced by ingot elongation. In practice, for normal growth without any difficulty, the upper limit of the growth rate r is approximately 2 mm/hour, however. Thus, it is preferable that the growth rate r ranges 450 μm/hour<r≦2 mm/hour.

The slicing of the ingot 9 into the substrates having the thickness a is followed by removal of layers damaged by the slicing, and subsequent double side grinding of each of the substrates to flatten the surfaces thereof. The substrates are ground, to thereby remove around 100 μm each.

It is preferable that the thickness of the substrates (group III nitride substrates) thus produced is not less than 100 μm and not more than 600 μm. It is because the thickness of the substrates necessary to handle them without cracking thereof is at least 100 μm. Also, the thickness of the substrates greater than 600 μm leads to difficulty in cleavage during semiconductor device production, or to an increase in the amount to be removed by back lapping, therefore adversely affecting the semiconductor device productivity. Thus, it is preferable that the thickness of the substrates is not less than 100 μm and not more than 600 μm.

Advantages

The method of making the conductive group III nitride single crystal substrate in this embodiment allows the SiH₂Cl₂ diluted with N₂ or Ar to inhibit the reaction between the SiH₂Cl₂ and NH₃ gas phases, and therefore the group III nitride single crystal to be grown fast and have the desired specific resistance.

Also, the above method of making the conductive group III nitride single crystal substrate allows the group III nitride single crystal to be grown at a growth rate ranging greater than 450 μm/hour and not greater than 2 mm/hour, and therefore the long sized ingot formed from that group III nitride single crystal having the desired specific resistance to be fabricated for a short period of time, and thus the conductive group III nitride single crystal substrate to be fabricated from that ingot at low cost.

### Example 1

Now, described is Example 1 of the method of making the conductive group III nitride single crystal substrate. GaN single crystal ingots are fabricated by the HVPE as a group III nitride single crystal, using a 56 mm diameter GaN single crystal (0001) substrate as a seed crystal therefor. Herein, the group III nitride single crystals are AlₓIn_{y}Ga_{1-x-y}N (0≦x≦1, 0≦y≦1, 0≦x+y≦1), of which the GaN single crystals are described as one example.

The partial pressure of each gas fed is as follows: the partial pressure of a GaCl gas fed for a group III raw material gas is 3×10⁻² atm, the partial pressure of an NH₃ gas fed for a group V raw material gas is 20×10⁻² atm, and the partial pressure of a H₂ gas fed is 25×10⁻² atm. Also used for a doping raw material gas is a SiH₂Cl₂ gas diluted with N₂ to have a specified concentration of 300 ppm. The flow of the N₂ diluted SiH₂Cl₂ gas fed is then adjusted to produce partial pressures of 0 atm, 0.14×10⁻⁶ atm, 0.29×10⁻⁶ atm, 0.57×10⁻⁶ atm, 1.14×10⁻⁶ atm, and 2.86×10⁻⁶ atm.

Also, the growth area is in a range of 52 mm in diameter. The growth rate is 600 μm/hour. The thickness of the ingots is 3 mm.

Using the wafer slicer, 600 μm thick GaN substrates are cut out from the fore ends of all the resultant ingots, respectively, in such a manner that their respective principal surfaces are oriented to (0001). The upper and lower surfaces of each of the GaN substrates are mirror ground, resulting in 400 μm thick GaN substrates.

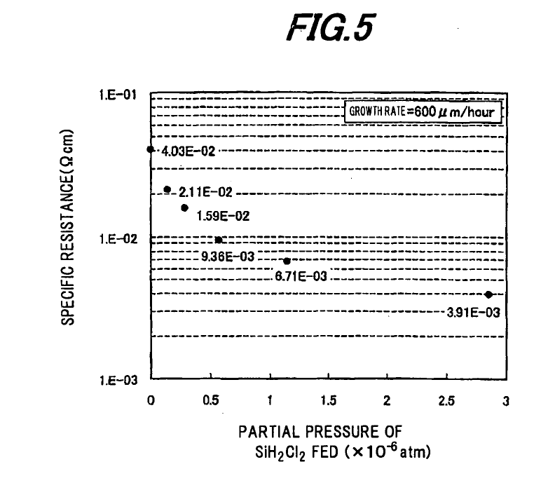

FIG. 5 is a graph showing the relationship of the specific resistance of the GaN substrates to the partial pressure of the SiH₂Cl₂ gas fed in Example 1. The specific resistance of the GaN substrates is measured by a four probe method. Also, the area to measure is the center of the GaN substrates.

From the measured results shown in FIG. 5, it is found that the N₂ diluted SiH₂Cl₂ gas having the concentration of 300 ppm used for the doping raw material gas allows the control of the specific resistance of the resultant GaN single crystal ingots at the partial pressure of the SiH₂Cl₂ gas fed even under the fast growth condition of 600 μm/hour.

### Example 2

Next, described is Example 2 of the method of making the conductive group III nitride single crystal substrate. GaN single crystal ingots are fabricated by the HVPE, using a 56 mm diameter GaN single crystal (0001) substrate as a seed crystal therefor.

The partial pressure of each gas fed is as follows: the partial pressure of a GaCl gas fed for a group III raw material gas is 6×10⁻² atm, the partial pressure of an NH₃ gas fed for a group V raw material gas is 35×10⁻² atm, and the partial pressure of a H₂ gas fed is 25×10⁻² atm. Also used for a doping raw material gas is a SiH₂Cl₂ gas diluted with N₂ to have a specified concentration of 300 ppm. The flow of the N₂ diluted SiH₂Cl₂ gas fed is then adjusted to produce partial pressures of 0 atm, 0.14×10⁻⁶ atm, 0.29×10⁻⁶ atm, 0.57×10⁻⁶ atm, 1.14×10⁻⁶ atm, and 2.86×10⁻⁶ atm.

Also, the growth area is in a range of 52 mm in diameter. The growth rate is 2 mm/hour. The thickness of the ingots is 3 mm.

Using the wafer slicer, 600 μm thick GaN substrates are cut out from the fore ends of all the resultant ingots, respectively, in such a manner that their respective principal surfaces are oriented to (0001). The upper and lower surfaces of each of the GaN substrates are mirror ground, resulting in 400 μm thick GaN substrates.

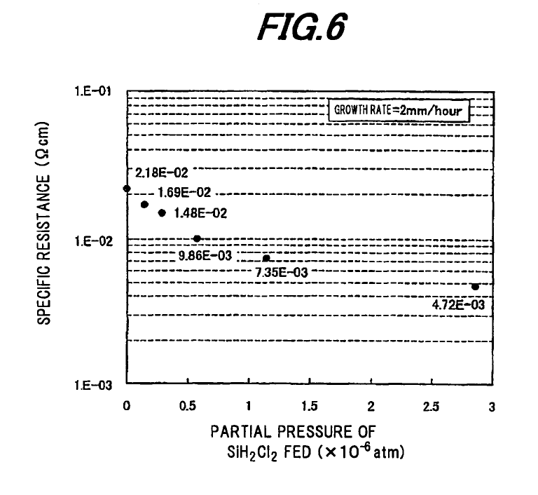

FIG. 6 is a graph showing the relationship of the specific resistance of the GaN substrates to the partial pressure of the SiH₂Cl₂ gas fed in Example 2. The specific resistance of the GaN substrates is measured by the four probe method. Also, the area to measure is the center of the GaN substrates.

From the measured results shown in FIG. 6, it is found that the N₂ diluted SiH₂Cl₂ gas having the concentration of 300 ppm used for the doping raw material gas allows the control of the specific resistance of the resultant GaN single crystal ingots at the partial pressure of the SiH₂Cl₂ gas fed even under the fast growth condition of 2 mm/hour.

### Example 3

Next, described is Example 3 of the method of making the conductive group III nitride single crystal substrate. GaN single crystal ingots are fabricated by the HVPE, using a 56 mm diameter GaN single crystal (0001) substrate as a seed crystal therefor.

The partial pressure of each gas fed is as follows: the partial pressure of a GaCl gas fed for a group III raw material gas is 2×10⁻² atm, the partial pressure of an NH₃ gas fed for a group V raw material gas is 13×10⁻² atm, and the partial pressure of a H₂ gas fed is 25×10⁻² atm. Also used for a doping raw material gas is a SiH₂Cl₂ gas diluted with N₂ to have a specified concentration of 300 ppm. The flow of the N₂ diluted SiH₂Cl₂ gas fed is then adjusted to produce partial pressures of 0 atm, 0.14×10⁻⁶ atm, 0.29×10⁻⁶ atm, 0.57×10⁻⁶ atm, 1.14×10⁻⁶ atm, and 2.86×10⁻⁶ atm.

Also, the growth area is in a range of 52 mm in diameter. The growth rate is 455 μm/hour. The thickness of the ingots is 3 mm.

Using the wafer slicer, 600 μm thick GaN substrates are cut out from the fore ends of all the resultant ingots, respectively, in such a manner that their respective principal surfaces are oriented to (0001). The upper and lower surfaces of each of the GaN substrates are mirror ground, resulting in 400 μm thick GaN substrates.

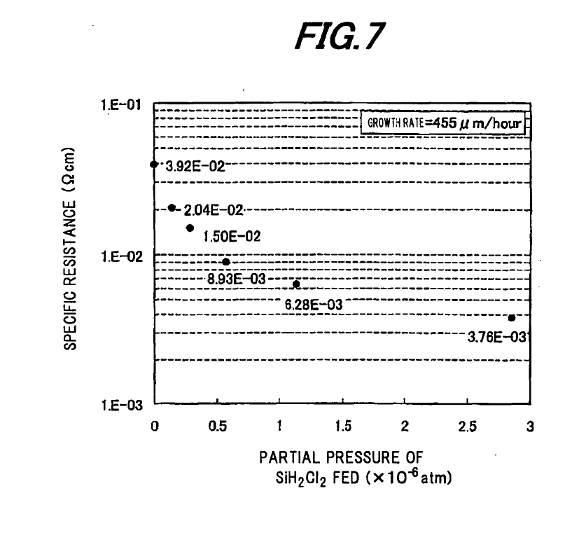

FIG. 7 is a graph showing the relationship of the specific resistance of the GaN substrates to the partial pressure of the SiH₂Cl₂ gas fed in Example 3. The specific resistance of the GaN substrates is measured by the four probe method. Also, the area to measure is the center of the GaN substrates.

From the measured results shown in FIG. 7, it is found that the N₂ diluted SiH₂Cl₂ gas having the concentration of 300 ppm used for the doping raw material gas allows the control of the specific resistance of the resultant GaN single crystal ingots at the partial pressure of the SiH₂Cl₂ gas fed even under the fast growth condition of 455 μm/hour.

### Example 4

Next, described is Example 4 of the method of making the conductive group III nitride single crystal substrate. GaN single crystal ingots are fabricated only by replacing N₂ with Ar for the SiH₂Cl₂ diluting gas in Examples 1 to 3 above. Also, GaN substrates are fabricated in the same manner as in Examples 1 to 3 above.

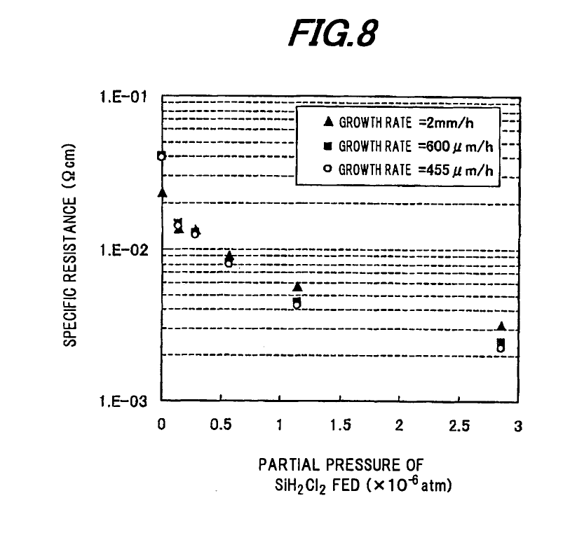

FIG. 8 is a graph showing the relationship of the specific resistance of the GaN substrates to the partial pressure of the SiH₂Cl₂ gas fed in Example 4. The specific resistance of the GaN substrates is measured in the same manner as in Examples 1 to 3 above. From the measured results shown in FIG. 8, the resultant GaN substrates doped with the Ar diluted SiH₂Cl₂ gas have better conductivities than those doped with the N₂ diluted SiH₂Cl₂ gas.

### Example 5

Next, described is Example 5 of the method of making the conductive group III nitride single crystal substrate. GaN single crystal ingots are fabricated by the HVPE, using a 56 mm diameter GaN single crystal (0001) substrate as a seed crystal therefor.

The partial pressure of each gas fed is as follows: the partial pressure of a GaCl gas fed for a group III raw material gas is 6.3×10⁻² atm, the partial pressure of an NH₃ gas fed for a group V raw material gas is 36×10⁻² atm, and the partial pressure of a H₂ gas fed is 25×10⁻² atm. Also, the growth area is in a range of 52 mm in diameter. The growth rate is 2.1 mm/hour.

Under these conditions, micro cracks are observed in the ingots. Consequently, it is found that Example 5 is not suitable for the GaN substrate production method.

### Example 6

Next, described is Example 6 of the method of making the conductive group III nitride single crystal substrate. A GaN single crystal ingot is fabricated by the HVPE, using a 56 mm diameter and 400 μm thick GaN single crystal (0001) substrate as a seed crystal therefor.

The partial pressure of each gas fed is as follows: the partial pressure of a GaCl gas fed for a group III raw material gas is 3×10⁻² atm, the partial pressure of an NH₃ gas fed for a group V raw material gas is 20×10⁻² atm, and the partial pressure of a H₂ gas fed is 25×10⁻² atm. Also used for a doping raw material gas is a SiH₂Cl₂ gas diluted with N₂ to have a specified concentration of 300 ppm. The flow of the N₂ diluted SiH₂Cl₂ gas fed is then adjusted to produce a partial pressure of 0.57×10⁶ atm.

Also, the growth area is in a range of 52 mm in diameter. The growth rate is 600 μm/hour. The ingot is grown to be 15 mm thick, and is sliced using the wafer slicer and taking a margin to be cut as being 1 mm, to result in ten 600 μm thick GaN substrates.

Using the wafer slicer, ten 600 μm thick GaN substrates are fabricated from the grown ingot in such a manner that their respective principal surfaces are oriented to (0001). The upper and lower surfaces of each of these GaN substrates are mirror ground, resulting in 400 μm thick GaN substrates having their respective principal surfaces oriented to (0001).

For each of the resultant GaN substrates, its specific resistance is measured by the four probe method. Also, the area to measure is the center of the GaN substrates. From the measured results, the GaN substrates all have a specific resistance of 9.4×10⁻³ Ωcm.

In this embodiment, the time required for introducing the seed crystal and taking it out after growth is 30 minutes, the time required for increasing temperature from room temperature to growth temperature is 1 hour, and the time required for decreasing temperature from growth temperature to room temperature is 1 hour. Also, the growth time is 24 hours and 20 minutes. Therefore, the time required for growing one substrate is 2 hours and 41 minutes.

### Example 7

Next, described is Example 7 of the method of making the conductive group III nitride single crystal substrate. A GaN single crystal ingot is fabricated by the HVPE, using a 56 mm diameter and 400 μm thick GaN single crystal (0001) substrate as a seed crystal therefor.

The partial pressure of each gas fed is as follows: the partial pressure of a GaCl gas fed for a group III raw material gas is 3×10⁻² atm, the partial pressure of an NH₃ gas fed for a group V raw material gas is 20×10⁻² atm, and the partial pressure of a H₂ gas fed is 25×10⁻² atm. Also used for a doping raw material gas is a SiH₂Cl₂ gas diluted with N₂ to have a specified concentration of 300 ppm. The flow of the N₂ diluted SiH₂Cl₂ gas fed is then adjusted to produce a partial pressure of 0.57×10⁻⁶ atm.

Also, the growth area is in a range of 52 mm in diameter. The growth rate is 600 μm/hour. The ingot is 20 mm thick.

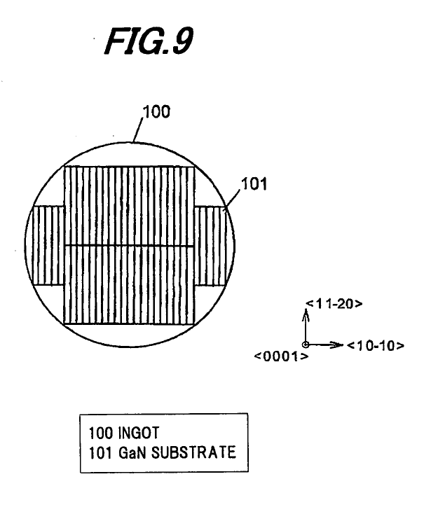

FIG. 9 is a schematic diagram showing the sliced GaN substrate in Example 7. Using the wafer slicer, fifty 20 mm square sized 600 μm thick GaN substrates 101 are fabricated from the 20 mm thick ingot 100 shown in FIG. 9 in such a manner that their respective principal surfaces are oriented to (10-10). The slicing is performed in such a manner as to result in forty GaN substrates 101 in the middle of the ingot 100 and ten GaN substrates 101 in peripheral portions of the ingot 100, as shown in FIG. 9. Also, the upper and lower surfaces of each of the resultant GaN substrates 101 are mirror ground.

The above-described method results in the fifty 20 mm square sized 400 μm thick GaN substrates 101 having their respective principal surfaces oriented to (10-10). For each of the resultant GaN substrates, its specific resistance is measured by the four probe method. Also, the area to measure is the center of the GaN substrates. From the measured results, the GaN substrates all have a specific resistance of 8.2×10⁻³ Ωcm.

### Example 8

Next, described is Example 8 of the method of making the conductive group III nitride single crystal substrate. GaN single crystal ingots are fabricated by the HVPE, using a 56 mm diameter 400 μm thick GaN single crystal (0001) substrate as a seed crystal therefor.

The ingots are fabricated in the following conditions: Used for a doping raw material gas are SiH₂Cl₂ gases diluted with Ar and N₂ respectively to have a specified concentration of 300 ppm. The flow of the Ar and N₂ diluted SiH₂Cl₂ gases respectively fed is then adjusted to produce a partial pressure of 8.6×10⁻⁸ atm. Also, a H₂ gas is fed at a partial pressure of 25×10⁻² atm, and an NH₃ gas is fed at partial pressures of 4.8×10⁻² atm, 9.5×10⁻¹ atm, 14.3×10⁻² atm, and 17 atm.

Also, the growth area is in a range of 52 mm in diameter. The partial pressure of a GaCl gas fed is adjusted in a range of from 5×10⁻³ atm to 8×10⁻³ atm, so that the growth rate is 100 μm/hour. This results in the 3 mm thick GaN single crystal ingots.

Using the wafer slicer, 600 μm thick GaN substrates are cut out from the fore ends of all the resultant ingots, respectively, in such a manner that their respective principal surfaces are oriented to (0001). The upper and lower surfaces of each of the GaN substrates are mirror ground, resulting in 400 μm thick GaN substrates.

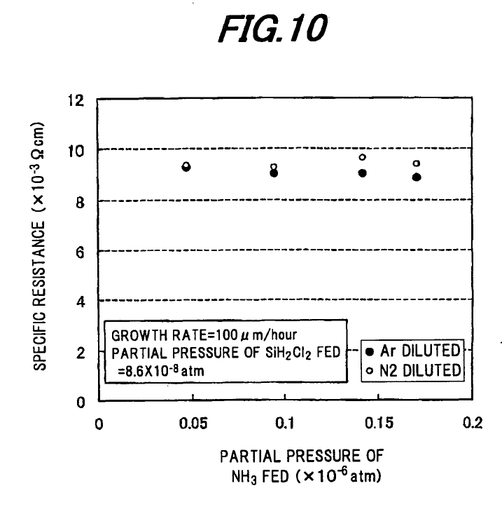

FIG. 10 is a graph showing the relationship of the specific resistance of the GaN substrates to the partial pressure of the NH₃ gas fed in Example 8.

From the measured results shown in FIG. 10, it is found that the Ar or N₂ diluted SiH₂Cl₂ gas having the concentration of 300 ppm used for the doping raw material gas allows no variation of the specific resistance of the resultant ingots even when the partial pressure of the NH₃ gas fed is varied.

The Ar or N₂ diluted SiH₂Cl₂ gas having the specified concentration used for the doping raw material gas therefore also allows the ingots fabricated in the fast growth conditions to have good conductivities.

The inventors have verified that the above feature is common to all group III nitride semiconductors grown using an NH₃ raw material. In this verification, the partial pressure of AlCl₃, InCl₃, and GaCl₃ fed for a group III raw material have properly been adjusted. A GaN single crystal substrate has been used for InN ingot growth as a seed crystal, and an AlN single crystal substrate has been used for AlN or AlInGaN single crystal ingot growth.

### Example 9

Using Al₂O₃, GaAs, Si as a seed crystal and these seed crystals with a patterned mask formed thereon, an experiment is performed in the same manner as in Example 1. Its results are the same as those of Example 1.

### Comparative Example 1

In Comparative example 1, using a GaAs (111) substrate as a seed crystal, a GaN single crystal ingot is fabricated thereon by the HVPE.

The ingot is grown, first at 500° C. for 1 hour feeding a GaCl gas at a partial pressure of 2×10⁻³ atm, an NH₃ gas at a partial pressure of 4.8×10⁻² atm, and a H₂ gas at a partial pressure of 0.1 atm, and then at an increased temperature of the GaAs substrate of 1050° C. for 1 hour.

The ingot is further grown for 1 hour feeding the GaCl gas at an increased partial pressure of 8×10⁻³ atm, and subsequently further grown for 5 hours feeding a H₂ diluted SiH₂Cl₂ gas at a partial pressure of 2×10⁻⁶ atm, which is used for a doping raw material gas.

The growth of the ingot is followed by removal of damaged layers of the GaAs substrate, resulting in a 600 μm thick GaN substrate. Subsequently, the upper and lower surfaces of the GaN substrate are mirror ground, resulting in a 400 μm thick GaN substrate. The specific resistance of the resultant GaN substrate measured by the four probe method as in each Example is 3.3×10⁻³ Ωcm.

The time required for introducing the seed crystal and taking it out after growth is 30 minutes. The time required for increasing temperature is 1 hour, and the time required for decreasing temperature is 1 hour. With the method in Comparative example 1, the time required for growing one GaN substrate is therefore 10 hours and 30 minutes.

In Example 6, the time for growing one GaN substrate can be shortened compared to Comparative example 1. It is therefore possible to produce the conductive GaN substrate at low cost.

### Comparative Example 2

In Comparative example 2, GaN single crystal ingots are fabricated by the HVPE, using a 56 mm diameter 400 μm thick GaN single crystal (0001) substrate as a seed crystal therefor.

The partial pressure of each gas fed is as follows: the partial pressure of a GaCl gas fed for a group III raw material gas is 3×10⁻² atm, the partial pressure of an NH₃ gas fed for a group V raw material gas is 20×10⁻² atm, and the partial pressure of a H₂ gas fed is 25×10⁻² atm. Also used for a doping raw material gas is a SiH₂Cl₂ gas diluted with He to have a specified concentration of 300 ppm. The flow of the He diluted SiH₂Cl₂ gas fed is then adjusted to produce partial pressures of 0 atm, 0.14×10⁻⁶ atm, 0.29×10⁻⁶ atm, 0.57×10⁻⁶ atm, 1.14×10⁻⁶ atm, and 2.86×10⁻⁶ atm.

Also, the growth area is in a range of 52 mm in diameter. The growth rate is 600 μm/hour. The ingot is 3 mm thick.

Using the wafer slicer, 600 μm thick GaN substrates are cut out from the fore ends of all the resultant ingots, respectively, in such a manner that their respective principal surfaces are oriented to (0001). The upper and lower surfaces of each of the GaN substrates are mirror ground, resulting in 400 μm thick GaN substrates.

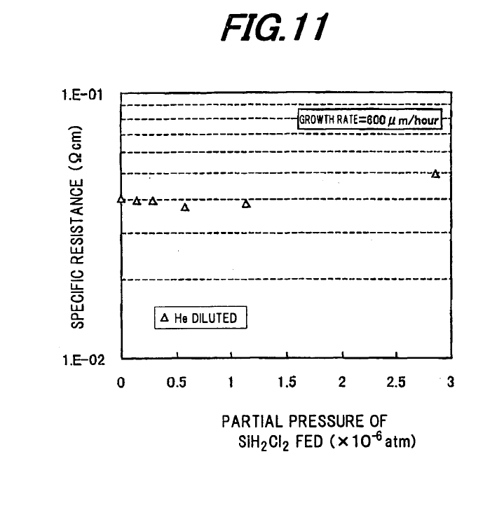

FIG. 11 is a graph showing the relationship of the specific resistance of the GaN substrates to the partial pressure of the SiH₂Cl₂ gas fed in Comparative example 2. The specific resistance of the GaN substrates is measured by the four probe method. Also, the area to measure is the center of the GaN substrates.

From the measured results shown in FIG. 11, it is found that the He diluted SiH₂Cl₂ gas having the concentration of 300 ppm used for the doping raw material gas allows no control of the specific resistance of the resultant ingots at the partial pressure of the SiH₂Cl₂ gas fed under the fast growth condition of 600 μm/hour. This is considered to be caused by He having a very large diffusion coefficient compared to N₂ or Ar, and therefore allowing no inhibition of the reaction between the NH₃ and SiH₂Cl₂ gas phases.

Although the invention has been described with respect to the above embodiments, the above embodiments are not intended to limit the appended claims. Also, it should be noted that not all the combinations of the features described in the above embodiments are essential to the means for solving the problems of the invention.

What is claimed is:

1. A method of making a conductive group III nitride single crystal substrate, comprising:
feeding to a seed crystal a group III raw material gas, a group V raw material gas, and a doping raw material gas diluted with N₂ or Ar to have a predetermined concentration;
growing a group III nitride single crystal on the seed crystal at a growth rate of greater than 450 μm/hour and not greater than 2 mm/hour; and
doping the group III nitride single crystal with an impurity contained in the doping raw material gas,
wherein the doping raw material gas is diluted to be inhibited from reacting with the group V raw material gas so as to allow the group III nitride single crystal to have a specific resistance of not less than 1×10⁻³ Ωcm and not more than 1×10⁻² Ωcm.

2. The method according to claim 1, wherein the doping raw material gas is fed to the seed crystal at a partial pressure of not less than 0.5×10⁻⁶ atm.

3. The method according to claim 2, wherein the doping raw material gas contains SiH₂Cl₂.

4. The method according to claim 3, wherein the group III raw material gas is produced by feeding a chloride gas to one group III raw material of In, Al or Ga heated at a temperature of from 500° C. to 900° C.

5. The method according to claim 4, wherein the group V raw material gas comprises NH₃.

6. The method according to claim 5, wherein the seed crystal comprises one of crystals of Al₂O₃, GaAs, Si, GaN and AlN or one of the crystals with a patterned mask formed thereon.

7. The method according to claim 6, wherein the group III nitride single crystal comprises AlₓIn_{y}Ga_{1-x-y}N (0≦x≦1, 0≦y≦1, 0≦x+y≦1).

8. The method according to claim 7, further comprising:
slicing the group III nitride single crystal at any crystalline plane into substrates; and
double side grinding the substrates so that the thickness of the substrates produced by the slicing is not less than 100 μm and not more than 600 μm.
